(19) United States
(12) Patent Application Publication
(10) Pub. No.: US 2013/0026524 A1
(43) Pub. Date: Jan. 31, 2013

(54) LIGHT EMITTING DIODE

(71) Applicants: Chung-I CHIANG, Yangmei City (TW); Chuan-Fa Lin, Yangmei City (TW); Ching-Huan Liao, Yangmei City (TW)

(72) Inventors: Chung-I CHIANG, Yangmei City (TW); Chuan-Fa Lin, Yangmei City (TW); Ching-Huan Liao, Yangmei City (TW)

(73) Assignee: WALSIN LIHWA CORPORATION, Taoyuan (TW)

(21) Appl. No.: 13/563,402

(22) Filed: Jul. 31, 2012

Related U.S. Application Data
(60) Provisional application No. 61/513,659, filed on Jul. 31, 2011.

(30) Foreign Application Priority Data
May 28, 2012 (TW) 101119013

(51) Int. Cl. H01L 33/44

(52) U.S. Cl. 257/98; 257/E33.061

(57) ABSTRACT

A light emitting diode (LED) is provided. The LED comprises a semiconductor composite layer stacked laterally and a phosphor substrate. The phosphor substrate covers a lateral surface of the semiconductor composite layer.

This application claims the benefit of U.S. provisional application Ser. No. 61/513,659, filed Jul. 31, 2011, and the benefit of Taiwan application Serial No. 101119013, filed May 28, 2012, the subject matters of which are incorporated herein by reference.

### BACKGROUND OF THE INVENTION

1. Field of the Invention

The invention relates in general to a light emitting diode (LED), and more particularly to an LED capable of increasing light extraction efficiency.

2. Description of the Related Art

Along with the advance in technology, various lighting technologies are invented. The LED marks a significant milestone in the development of lighting technology. The LED has been widely used in various electronic devices and lamps due to its advantages such as high efficiency, long lifespan and robustness.

The LED mainly can be divided into two categories: the horizontal LED and the vertical LED. According to the horizontal LED, two electrodes are disposed on the same side of the epitaxial layer of the LED chip. The horizontal LED can be further divided into two types of structures depending on whether the LED is connected to the electrodes by way of wire-bounding or flip-chip. According to the vertical LED, two electrodes are respectively disposed on different sides of the epitaxial layer. Regardless of the structure of the LED being vertical or horizontal, the extending direction of the epitaxial layer of the LED is parallel to the electrodes. Since the surface of the LED structure that faces the circuit board has the largest light extraction, the light extraction efficiency deteriorates. Moreover, as the LED needs to be packaged with an external packaging adhesive, more costs and labor hours incur in the manufacturing process.

Therefore, how to provide an LED having the advantages of simplifying manufacturing process, reducing cost and increasing light extraction efficiency has become a prominent task for the industries.

### SUMMARY OF THE INVENTION

The invention is directed to a light emitting diode (LED) having the advantages of increasing light extraction efficiency, simplifying manufacturing process and reducing manufacturing cost.

According to an embodiment of the present invention, an LED comprising a semiconductor composite layer stacked laterally and a phosphor substrate is provided. The phosphor substrate covers a lateral surface of the semiconductor composite layer.

According to another embodiment of the present invention, an LED comprising a semiconductor composite layer stacked laterally, a first phosphor substrate, a second phosphor substrate, a phosphor layer, a first electrode and a second electrode is provided. The semiconductor composite layer comprises a first semiconductor layer, a second semiconductor layer opposite to the first semiconductor layer, a light emitting layer, an upper surface and a bottom surface opposite to the upper surface. The upper surface and the bottom surface are respectively perpendicular to the first semiconductor layer and the second semiconductor layer. The light emitting layer is interposed between the first semiconductor layer and the second semiconductor layer. The first phosphor substrate covers the first semiconductor layer. The second phosphor substrate covers the second semiconductor layer. The phosphor layer covers the upper surface. The first electrode is disposed on the bottom surface and vertically connected to the first semiconductor layer. The second electrode is disposed on the bottom surface and vertically connected to the second semiconductor layer. The first phosphor substrate and the second phosphor substrate are interconnected.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows an external view of an LED according to an embodiment of the invention;

FIG. 1B shows a cross-sectional view along 1B-1B′ direction of FIG. 1A;

FIG. 1A′ shows an external view of an LED according to another embodiment of the invention;

FIG. 1B′ shows a cross-sectional view along 1B′-1B″ direction of FIG. 1A′;

FIG. 2 shows a cross-sectional view of an LED according to another embodiment of the invention; and

FIG. 3 shows a cross-sectional view of an LED according to another embodiment of the invention.

### DETAILED DESCRIPTION OF THE INVENTION

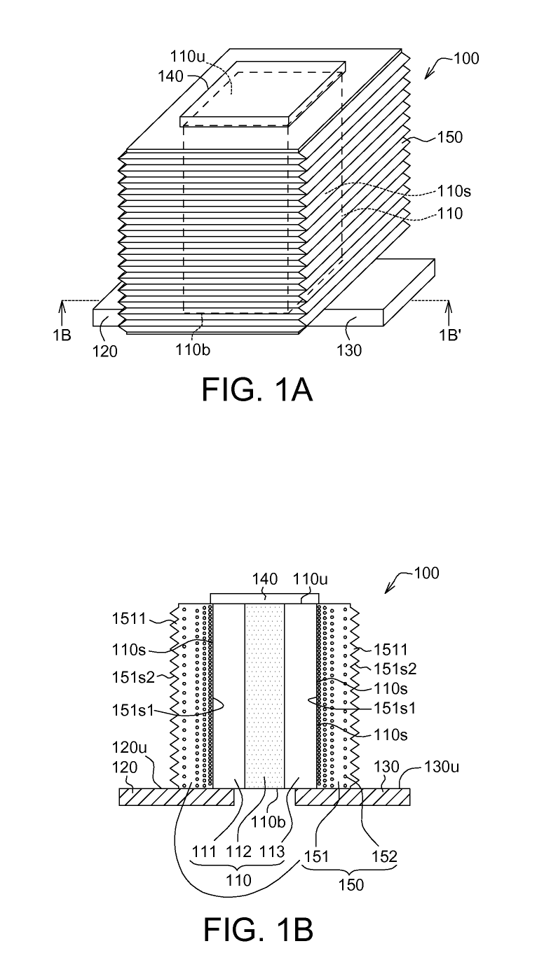

Referring to FIG. 1A, an external view of an LED 100 according to an embodiment of the invention is shown. The LED 100 comprises a semiconductor composite layer 110, a first electrode 120, a second electrode 130, a phosphor layer 140 and a phosphor substrate 150.

The semiconductor composite layer 110 has a lateral surface 110s, an upper surface 110u and a bottom surface 110b opposite to the upper surface 110u. The upper surface 110u is substantially parallel to the bottom surface 110b. The lateral surface 110s of the semiconductor composite layer 110 is substantially perpendicular to the upper surface 110u and the bottom surface 110b of the semiconductor composite layer 110. Due to the manufacturing tolerances or errors, the angle between the lateral surface 110s and the upper surface 110u or the bottom surface 110b of the semiconductor composite layer 110 may be slightly larger or smaller than 90 degrees.

In the present embodiment of the invention, the area of the lateral surface 110s of the semiconductor composite layer 110 is larger than that of the upper surface 110u and the bottom surface 110b. Based on such design, the light extraction efficiency of the lateral surface 110s of the semiconductor composite layer 110 is larger than that of the upper surface 110u and the bottom surface 110b. Therefore, the light emitted from the LED 100 is less likely to be shielded by the first electrode 120 and/or the second electrode 130, and the overall light extraction efficiency of the LED 100 is thus increased. In another embodiment, the area of the lateral surface 110s may be smaller than or equal to that of the upper surface 110u and the bottom surface 110b according to the design needs.

As indicated in FIG. 1A, the phosphor substrate 150 covers the lateral surface 110s of the semiconductor composite layer 110. In other words, the lateral surface 110s of the semiconductor composite layer 110 is completely surrounded by the phosphor substrate 150, so that the light (not illustrated) emitted from the lateral surface 110s of the semiconductor composite layer 110 may pass through the phosphor substrate 150. Therefore, the required mixed light is directly provided, and there is no need to additionally interpose any packaging adhesive.

Referring to FIG. 1B, a cross-sectional view along 1B-1B′ direction of FIG. 1A is shown. The semiconductor composite layer 110, being laterally stacked, comprises a first semiconductor layer 111, a light emitting layer 112 and a second semiconductor layer 113. The first semiconductor layer 111 is substantially parallel to the second semiconductor layer 113, and the light emitting layer 112 is interposed between the first semiconductor layer 111 and the second semiconductor layer 113.

The semiconductor composite layer 110 may be formed by an ordinary semiconductor manufacturing process (such as thin film deposition, lithography, etching, and doping). The first semiconductor layer 111 is such as one of a P-type semiconductor layer and an N-type semiconductor layer, and the second semiconductor layer 113 is the other one of the P-type semiconductor layer and N-type semiconductor layer. The P-type semiconductor layer is a nitrogen-based semiconductor layer doped with trivalent elements such as boron (B), indium (In), gallium (Ga) or aluminum (Al). The N-type semiconductor layer is a nitrogen-based semiconductor layer doped with pentavalent elements such as phosphorus (P), antimony (Sb), or arsenide (As). The light emitting layer 112 may be realized by a III-V group dual-element compound semiconductor (such as gallium arsenide (GaAs), indium phosphide (InP), gallium phosphide (GaP), or gallium nitride (GaN)), a III-V group multi-element compound semiconductor (such as aluminum gallium arsenide (AlGaAs), gallium arsenic phosphide (GaAsP), aluminum gallium indium phosphide (AlGaInP) or aluminum indium gallium arsenide (AlInGaAs)) or a II-VI group dual-element compound semiconductor (such as cadmium selenide (CdSe), cadmium sulfide (CdS) or zinc selenide (ZnSe)).

As indicated in FIG. 1B, the first electrode 120 is disposed on the bottom surface 110b of the semiconductor composite layer 110 and vertically connected to the first semiconductor layer 111. In greater details, the top surface 120u of the first electrode 120 is connected to the bottom surface 110b of the semiconductor composite layer 110, wherein the top surface 120u is substantially perpendicular to the lateral surface 110s of the first semiconductor layer 111. The second electrode 130 is disposed on the bottom surface 110b of the semiconductor composite layer 110 and vertically connected to the second semiconductor layer 113. In greater details, the top surface 130u of the second electrode 130 is connected to the bottom surface 110b of the semiconductor composite layer 110, wherein the top surface 130u is substantially perpendicular to the lateral surface 110s of the second semiconductor layer 113.

The LED 100 is disposed on a circuit board (not illustrated) through the first electrode 120 and the second electrode 130. That is, the bottom surface 110b of the LED 100 faces the circuit board, but the lateral surface 110s of the LED 100 does not face the circuit board, so that the light emitted from the lateral surface 110s of the semiconductor composite layer 110 is not shielded by the circuit board, and the overall light extraction efficiency of the LED 100 is thus increased.

In the present embodiment of the invention, the light extraction efficiency of the upper surface of the LED 100 is more than 30%, the light extraction efficiency of the bottom surface is more than 5%, the light extraction efficiency of the lateral surface is more than 45%, and the overall light extraction efficiency is at least above 80%. In comparison to the overall light extraction efficiency of the conventional LED which ranges 60˜70% at most, the overall light extraction efficiency of the LED 100 according to the present embodiment of the invention is increased by at least 10˜20%.

As indicated in FIG. 1B, the phosphor layer 140 may cover the upper surface 110u of the semiconductor composite layer 110 by way of bonding or coating. Preferably but not restrictively, the phosphor layer 140 covers the entire upper surface 110u of the semiconductor composite layer 110, so that the light emitted from the upper surface 110u of the semiconductor composite layer 110 passes through the phosphor layer 140. In addition, the phosphor layer 140 may be a phosphor adhesive layer or a phosphor substrate. The phosphor adhesive layer may be a packaging adhesive doped with the phosphor powder available in the market such as a yttrium aluminum garnet (YAG) phosphor powder, a zinc sulfide (ZnS) phosphor powder and a silicate phosphor powder, but the invention is not limited thereto. The phosphor substrate may be similar to the phosphor substrate 150, 250 or 350 according to the embodiments of the present invention.

The phosphor substrate 150 comprises a transparent substrate 151 and a plurality of fluorescent particles 152 doped in the transparent substrate 151.

The transparent substrate 151 has a first surface 151s1 and a second surface 151s2 opposite to the first surface 151s1. The first surface 151s1 of the transparent substrate 151 covers the lateral surface 110s of the semiconductor composite layer 110. In the present embodiment of the invention, the transparent substrate 151 has a plurality of roughened surfaces 1511 which destroys the total reflection angle of the light at the second surface 151s2 so as to increase the light extraction efficiency. However, the embodiments of the invention are not limited thereto. The transparent substrate 151 may also be realized by such as a mono-crystalline substrate, a poly-crystalline substrate, or a substrate made from transparent quartz, transparent glass or transparent high polymers.

The fluorescent particles 152 are distributed within the transparent substrate 151. Apart from being uniformly distributed within the transparent substrate 151, the distribution density of fluorescent particles 152 may gradually increase or decrease from the first surface 151s1 of the transparent substrate 151 towards the second surface 151s2, so that the refractive index of the phosphor substrate 150 gradually changes from the first surface 151s1 towards the second surface 151s2 to increase the light extraction efficiency. In the present embodiment of the invention, the distribution density of fluorescent particles 152 within the transparent substrate 151 may gradually decrease from the first surface 151s1 towards the second surface 151s2 as indicated in FIG. 1B. With the gradual change in the distribution density of fluorescent particles 152, the phosphor substrate 150 is optimized, and the phosphor substrate 150 is free of radical change in the refractive index at local regions, so that the light extraction quality is stabilized, and the light extraction efficiency is increased.

The transparent substrate 151 may also be optimized. For example, the distribution of the refractive index of the transparent substrate 151 may gradually increase or decrease from the first surface 151s1 towards the second surface 151s2 of the transparent substrate 151, such that the refractive index of the phosphor substrate 150 gradually changes from the first surface 151s1 towards the second surface 151s2 to increase the light extraction efficiency. By controlling the parameters or ingredients during the process of manufacturing the transparent substrate 151, the transparent substrate 151 on which the refractive indexes are different at local regions is provided to avoid the refractive index having radical change at local regions of the phosphor substrate 150, so that the light extraction quality is stabilized and the light extraction efficiency is increased. Under the design that the refractive index of the transparent substrate 151 gradually increases or decreases, whether to restrict the distribution of the fluorescent particles 152 doped within the transparent substrate 151 is determined according to actual needs.

Please now refer to FIG. 1A′ and 1B′. FIG. 1A′ shows an external view of an LED 100 according to another embodiment of the invention. FIG. 1B′ shows a cross-sectional view along 1B′-1B″ direction of FIG. 1A′. The LED 100′ of the present embodiment is different from the LED 100 of the previous embodiment in that the transparent substrate 151 of the LED 100′ does not have a roughened surface structure. Other elements and features are similar to that of the previous embodiment, and the similarities are not described herein.

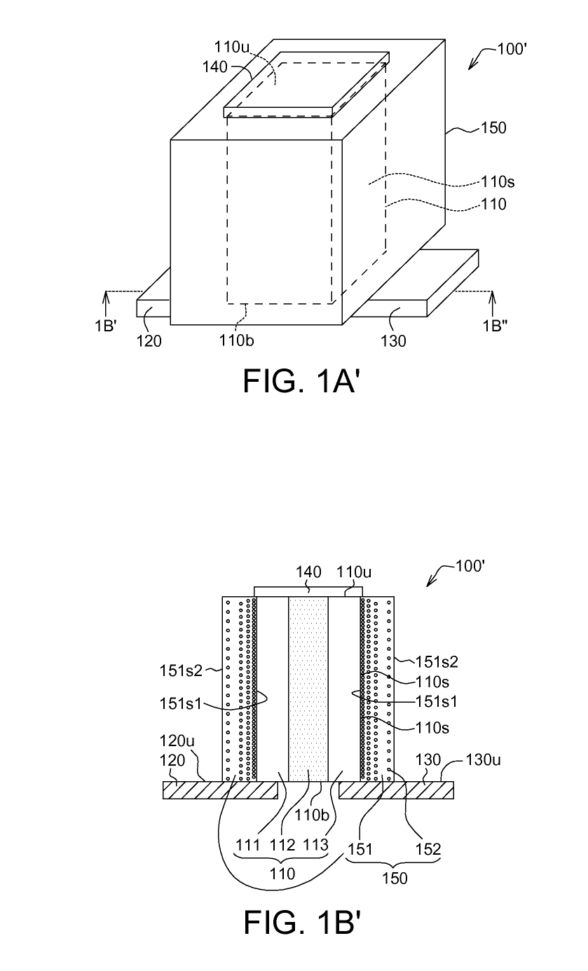

Referring to FIG. 2, a cross-sectional view of an LED 200 according to another embodiment of the invention is shown. The LED 200 comprises a semiconductor composite layer 110, a first electrode 120, a second electrode 130, a phosphor layer 140 and a phosphor substrate 250.

As indicated in FIG. 2, the phosphor substrate 250 covers the lateral surface 110s of the semiconductor composite layer 110. The lateral surface 110s of the semiconductor composite layer 110 is completely surrounded by the phosphor substrate 250, so that the light (not illustrated) emitted from the lateral surface 110s of the semiconductor composite layer 110 may pass 110 may pass through the phosphor substrate 250. Therefore, the required mixed light is directly provided, and there is no need to additionally interpose any packaging adhesive. The phosphor substrate 250 may be realized by a single-layered or multi-layered substrate structure. The disclosure below is exemplified by a dual-layered substrate structure, but in other embodiments, the number of substrate layers of the phosphor substrate 250 may be larger than three, and is determined according to actual needs.

The phosphor substrate 250 comprises a transparent substrate 251 and a plurality of fluorescent particles 152. The transparent substrate 251 is a dual-layered substrate, and comprises a first sub-transparent substrate 2511 and a second sub-transparent substrate 2512. The first sub-transparent substrate 2511 covers the lateral surface 110s of the semiconductor composite layer 110. The second sub-transparent substrate 2512 covers the lateral surface of the first sub-transparent substrate 2511. The materials of the first sub-transparent substrate 2511 and the second sub-transparent substrate 2512 may be similar to that of the transparent substrate 151, and the similarities are not described herein.

As indicated in FIG. 2, the fluorescent particles 152 are distributed within the first sub-transparent substrate 2511 and the second sub-transparent substrate 2512. The distribution density of fluorescent particles 152 within the first sub-transparent substrate 2511 is larger than the distribution density of the fluorescent particles 152 within the second sub-transparent substrate 2512, so that the distribution density of fluorescent particles 152 may gradually decrease from the first surface 251s1 of the transparent substrate 251 towards the second surface 251s2, but the invention is not limited thereto. In other embodiments, the distribution density of fluorescent particles within the first sub-transparent substrate is smaller than the distribution density of fluorescent particles of the second sub-transparent substrate, so that the distribution density of fluorescent particles may gradually increase from the first surface of the transparent substrate towards the second surface. With the gradual change in the distribution density of fluorescent particles 152, the phosphor substrate 150 is optimized to avoid the refractive index having radical change at local regions of the phosphor substrate 150, so that the light extraction quality is stabilized and the light extraction efficiency is increased.

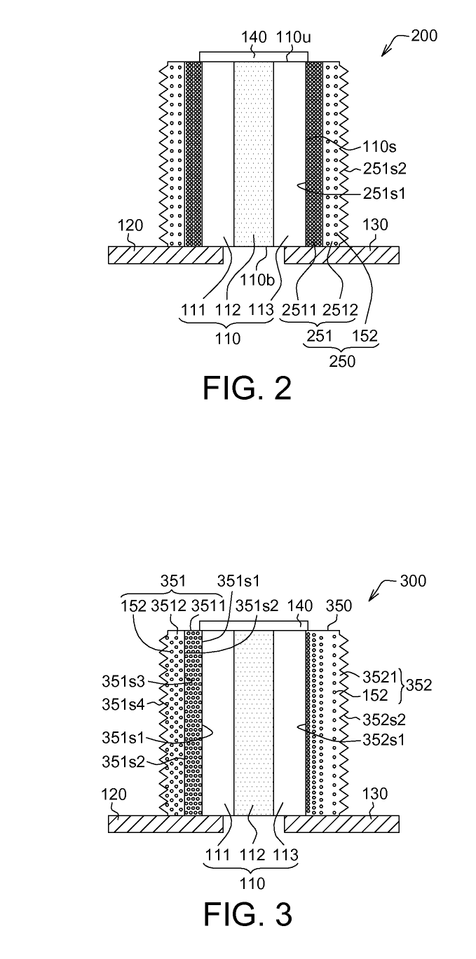

Referring to FIG. 3, a cross-sectional view of an LED 300 according to another embodiment of the invention is shown. The LED 300 comprises a semiconductor composite layer 110, a first electrode 120, a second electrode 130, a phosphor layer 140 and a phosphor substrate 350.

As indicated in FIG. 3, the phosphor substrate 350 covers the lateral surface 110s of the semiconductor composite layer 110. The lateral surface 110s of the semiconductor composite layer 110 is completely surrounded by the phosphor substrate 150, so that the light (not illustrated) emitted from the lateral surface 110s of the semiconductor composite layer 110 may pass through the phosphor substrate 150. Therefore, the required mixed light is directly provided, and there is no need to additionally interpose any packaging any packaging adhesive. The phosphor substrate 350 comprises a first phosphor substrate 351 and a second phosphor substrate 352, wherein the first phosphor substrate 351 is connected to the second phosphor substrate 352 by way of adhering or coupling, but the invention is not limited thereto. In another embodiment, the first phosphor substrate and the second phosphor substrate may also be integrally formed in one piece.

The first phosphor substrate 351 comprises a first sub-transparent substrate 3511 and a second sub-transparent substrate 3512. The first sub-transparent substrate 3511 is disposed on the semiconductor composite layer 110. The second sub-transparent substrate 3512 is disposed on the first sub-transparent substrate 3511. The materials of the first sub-transparent substrate 3511 and the second sub-transparent substrate 3512 may be similar to that of the transparent substrate 151, and the similarities are not described herein.

The first phosphor substrate 351 further comprises a plurality of fluorescent particles 152 distributed within the first sub-transparent substrate 3511 and the second sub-transparent substrate 3512. The distribution density of fluorescent particles 152 within the first sub-transparent substrate 3511 is larger than the distribution density of fluorescent particles 152 within the second sub-transparent substrate 3512, but the invention is not limited thereto. In another embodiment, the distribution density of fluorescent particles within the first sub-transparent substrate is smaller than the distribution density of fluorescent particles within the second sub-transparent substrate.

In another embodiment, the transparent substrate may be optimized. For example, the distribution of the refractive index of the first sub-transparent substrate 3511 may gradually increase or decrease from the first surface 351s1 of the first sub-transparent substrate 3511 towards the second surface 351s2. Based on such design, whether to restrict the distribution of the fluorescent particles 152 is determined according to actual needs. Furthermore, the distribution of the refractive index of the second sub-transparent substrate 3512 may gradually increase or decrease from the first surface 351s3 of the second sub-transparent substrate 3512 towards the second surface 351s4. Based on such design, whether to restrict the distribution of the fluorescent particles 152 is determined according to actual needs.

As indicated in FIG. 3, the second phosphor substrate 352 comprises a transparent substrate 3521 and a plurality of fluorescent particles 152. The first surface 352s1 of the transparent substrate 3521 is connected to the semiconductor composite layer 110. In addition, the materials of the transparent substrate 3521 may be similar to that of the transparent substrate 151, and the similarities are not described herein. The fluorescent particles 152 are distributed within the transparent substrate 3521. The distribution density of fluorescent particles 152 may gradually increase or decrease from the first surface 352s1 of the transparent substrate 3521 towards the second surface 352s2. In another embodiment, fluorescent particles 152 are uniformly distributed within the transparent substrate 3521.

The LED disclosed in the embodiments of the invention has many advantages exemplified below:

(1). In an embodiment, through the structure of the laterally stacked semiconductor composite layer, the surface with higher light extraction efficiency is disposed as a lateral surface, so that the light emitted from the LED is less likely to be shielded by the electrode and/or the circuit board, and the overall light extraction efficiency is increased.

(2). In an embodiment, the lateral surface of the semiconductor composite layer covers the phosphor substrate, so that the light emitted from the lateral surface passes through the phosphor substrate. As the required mixed light is directly provided, there is no need to additionally interpose any packaging adhesive, and the cost of the manufacturing process is thus reduced.

(3). In an embodiment, with gradual change in the distribution density and/or the distribution of the refractive index which is achieved by changing the distribution density of fluorescent particles within the phosphor substrate and/or the refractive index of the phosphor substrate, radical changes at local regions are avoided, so that the light extraction quality is stabilized and the light extraction efficiency is increased.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED), comprising:
a semiconductor composite layer stacked laterally; and
a phosphor substrate covering a lateral surface of the semiconductor composite layer.

2. The LED according to claim 1, wherein the phosphor substrate comprises:
a transparent substrate having a first surface and a second surface opposite to the first surface, wherein the first surface of the transparent substrate is connected to the lateral surface of the semiconductor composite layer; and
a plurality of fluorescent particles distributed within the transparent substrate, wherein the distribution density of the fluorescent particles gradually increases or decreases from the first surface of the transparent substrate towards the second surface of the transparent substrate.

3. The LED according to claim 1, wherein the phosphor substrate comprises a transparent substrate having a first surface and a second surface opposite to the first surface, the first surface of the transparent substrate is connected to the lateral surface of the semiconductor composite layer, and the distribution of the refractive index of the transparent substrate gradually increases or decreases from the first surface of the transparent substrate towards the second surface of the transparent substrate.

4. The LED according to claim 1, wherein the phosphor substrate comprises:
a first sub-transparent substrate covering the lateral surface of the semiconductor composite layer;
a second sub-transparent substrate covering the first sub-transparent substrate; and
a plurality of fluorescent particles distributed within the first sub-transparent substrate and the second sub-transparent substrate, wherein the distribution density of the fluorescent particles within the second sub-transparent substrate is larger or smaller than the distribution density of the fluorescent particles within the first sub-transparent substrate.

5. The LED according to claim 1, wherein the phosphor substrate comprises:
a first sub-transparent substrate covering the lateral surface of the semiconductor composite layer; and
a second sub-transparent substrate covering the first sub-transparent substrate, wherein the refractive index of the second sub-transparent substrate is larger or smaller than the refractive index of the first sub-transparent substrate.

6. The LED according to claim 1, wherein the semiconductor composite layer has an upper surface perpendicular to the lateral surface of the semiconductor composite layer, and the LED further comprises:
a phosphor layer covering the upper surface of the semiconductor composite layer.

7. The LED according to claim 1, wherein the semiconductor composite layer comprises a first semiconductor layer, a second semiconductor layer opposite to the first semiconductor layer, and a light emitting layer interposed between the first semiconductor layer and the second semiconductor layer.

8. The LED according to claim 7, wherein the first semiconductor layer is a P-type semiconductor layer and the second semiconductor layer is an N-type semiconductor layer.

9. The LED according to claim 7, wherein the first semiconductor layer is an N-type semiconductor layer and the second semiconductor layer is a P-type semiconductor layer.

10. An LED, comprising:
a laterally stacked semiconductor composite layer comprising a first semiconductor layer, a second semiconductor layer opposite to the first semiconductor layer, a light emitting layer, an upper surface and a bottom surface opposite to the upper surface, wherein the upper surface and the bottom surface are respectively perpendicular to the first semiconductor layer and the second semiconductor layer, and the light emitting layer is interposed between the first semiconductor layer and the second semiconductor layer;
a first phosphor substrate covering the first semiconductor layer;
a second phosphor substrate covering the second semiconductor layer;
a phosphor layer covering the upper surface;
a first electrode disposed on the bottom surface and vertically connected to the first semiconductor layer; and
a second electrode disposed on the bottom surface and vertically connected to the second semiconductor layer;
wherein the first phosphor substrate and the second phosphor substrate are interconnected.

11. The LED according to claim 10, wherein the phosphor layer is a phosphor adhesive layer or a phosphor substrate.

12. The LED according to claim 10, wherein each of at least one of the first phosphor substrate and the second phosphor substrate comprises:
a transparent substrate having a first surface and a second surface opposite to the first surface, wherein the first surface of the transparent substrate is connected to the semiconductor composite layer; and
a plurality of fluorescent particles distributed within the transparent substrate, wherein the distribution density of the fluorescent particles gradually increases or decreases from the first surface of the transparent substrate towards the second surface of the transparent substrate.

13. The LED according to claim 10, wherein each of at least one of the first phosphor substrate and the second phosphor substrate comprises:
a transparent substrate having a first surface and a second surface opposite to the first surface, wherein the first surface of the transparent substrate is connected to the semiconductor composite layer, and the distribution of the refractive index of the transparent substrate gradually increases or decreases from the first surface of the transparent substrate towards the second surface of the transparent substrate.

14. The LED according to claim 10, wherein each of at least one of the first phosphor substrate and the second phosphor substrate comprises:
a first sub-transparent substrate covering the semiconductor composite layer;
a second sub-transparent substrate covering the first sub-transparent substrate; and
a plurality of fluorescent particles distributed within the first sub-transparent substrate and the second sub-transparent substrate, wherein the distribution density of the fluorescent particles within the second sub-transparent substrate is larger or smaller than the distribution density of the fluorescent particles of the first sub-transparent substrate.

15. The LED according to claim 10, wherein each of at least one of the first phosphor substrate and the second phosphor substrate comprises:
a first sub-transparent substrate covering the semiconductor composite layer; and
a second sub-transparent substrate covering the first sub-transparent substrate, wherein the refractive index of the second sub-transparent substrate is larger or smaller than the refractive index of the first sub-transparent substrate.

16. The LED according to claim 10, wherein the first semiconductor layer is a P-type semiconductor layer and the second semiconductor layer is an N-type semiconductor layer.

17. The LED according to claim 10, wherein the first semiconductor layer is an N-type semiconductor layer and the second semiconductor layer is a P-type semiconductor layer.
